(19) United States
(12) Patent Application Publication
(10) Pub. No.: US 2019/0180930 A1
(43) Pub. Date: Jun. 13, 2019

(54) DC-DC CONVERTER MODULE

(71) Applicant: Murata Manufacturing Co., Ltd., Nagaokakyo-shi (JP)

(72) Inventor: Hirokazu YAZAKI, Nagaokakyo-shi (JP)

(21) Appl. No.: 16/274,294

(22) Filed: Feb. 13, 2019

Related U.S. Application Data
(63) Continuation of application No. PCT/JP2017/030485, filed on Aug. 25, 2017.

(30) Foreign Application Priority Data
Sep. 21, 2016 (JP) 2016-184206

(51) Int. Cl. H01F 27/36; H02M 3/158; H05K 9/00; H05K 1/02; H05K 1/16

(52) U.S. Cl. CPC H01F 27/36; H02M 3/158; H05K 9/0024; H05K 2201/086; H05K 1/165; H05K 1/0233; H05K 2201/10015; H05K 1/0298

(57) ABSTRACT

A DC-DC converter module includes a substrate, first and second ground electrodes provided at the substrate, a switching-element-incorporating IC including an input end, an output end, and a first ground end, a coil element connected to the input end or the output end, a capacitor element including a first end connected to the input end or the output end and a second end connected to the first ground electrode, and a shield cover connected to the second ground electrode and covering at least one of the switching-element-incorporating IC, the coil element, and the capacitor element which is disposed on a surface of the substrate.

### CROSS REFERENCE TO RELATED APPLICATIONS

This application claims the benefit of priority to Japanese Patent Application No. 2016-184206 filed on Sep. 21, 2016 and is a Continuation Application of PCT Application No. PCT/JP2017/030485 filed on Aug. 25, 2017. The entire contents of each application are hereby incorporated herein by reference.

### BACKGROUND OF THE INVENTION

### 1. Field of the Invention

The present invention relates to a DC-DC converter module including a substrate and a shield cover.

### 2. Description of the Related Art

A DC-DC converter module having a configuration in which an IC including a switching element (hereinafter referred to as a switching-element-incorporating IC), a coil, and a capacitor (an input capacitor or an output capacitor), etc. are disposed at a substrate is known.

For example, Japanese Unexamined Patent Application Publication No. 2011-193724 discloses a DC-DC converter module in which the above-described switching-element-incorporating IC, the coil, etc. are covered with a shield cover. In this DC-DC converter module, the shield cover functions as a shield to shield noise emitted from, for example, the switching-element-incorporating IC. Noise emitted from the DC-DC converter module is able to therefore be reduced.

Such a shield cover is typically connected to the ground to increase a noise removal effect.

However, in a case in which a shield cover is connected to the ground of a capacitor, noise induced by the shield cover may flow to the input-side or output-side of a DC-DC converter module via the ground and the capacitor. Accordingly, even if the shield cover is connected to the ground, the noise removal effect of the shield cover may not be sufficiently obtained and the influence of noise on the input-side or output side of the DC-DC converter module may increase.

### SUMMARY OF THE INVENTION

Preferred embodiments of the present invention provide DC-DC converter modules in each of which a shield cover connected to the ground is provided and the flow of noise to the input side or output side thereof is reduced or prevented.

A DC-DC converter module according to a preferred embodiment of the present invention includes a substrate, a first ground electrode, and a second ground electrode which are provided at the substrate, a switching-element-incorporating IC including an input end, an output end, and a first ground end, a coil element connected to the input end or the output end, a capacitor element including a first end connected to the input end or the output end and a second end connected to the first ground electrode, and a shield cover that is connected to the second ground electrode and covers at least one of the switching-element-incorporating IC, the coil element, and the capacitor element which is disposed on a surface of the substrate.

In this configuration, the shield cover and the capacitor element, which are connected to the ground, are separated from each other. Accordingly, the flow of noise induced by the shield cover to the input side or output side of the DC-DC converter module via the capacitor element is reduced or prevented. The DC-DC converter module in which the flow of noise to the input side or the output side thereof is reduced or prevented is therefore able to be achieved.

A DC-DC converter module according to a preferred embodiment of the present invention includes a substrate, a ground electrode provided at the substrate, a switching-element-incorporating IC including an input end, an output end, and a first ground end, a coil element connected to the input end or the output end, a capacitor element including a first end connected to the input end or the output end and a second end connected to the ground electrode, and a shield cover that is connected to the ground electrode and covers at least one of the switching-element-incorporating IC, the coil element, and the capacitor element which is disposed on a surface of the substrate. The second end and the shield cover are physically connected and are electrically disconnected at a frequency higher than or equal to a predetermined frequency.

With this configuration, even if the second end of the capacitor element and the shield cover are physically connected, the shield cover is connected to the second ground electrode that is electrically different from the first ground electrode to which the capacitor element is connected at the predetermined frequency. Accordingly, the flow of noise induced by the shield cover to the input side or output side of the DC-DC converter module is reduced or prevented. The DC-DC converter module in which the flow of noise to the input or output side thereof is reduced or prevented is therefore able to be achieved.

In a DC-DC converter module according to a preferred embodiment of the present invention, an inductor that includes a predetermined inductance component at the predetermined frequency may be connected between the second end and the shield cover.

In a DC-DC converter module according to a preferred embodiment of the present invention, the inductor preferably a conductive pattern provided at the substrate. Since the inductor is provided using a conductive pattern provided at the substrate in this configuration, there is no need to separately provide an element. This facilitates manufacturing and reduces cost.

In a DC-DC converter module according to a preferred embodiment of the present invention, the inductor preferably includes an interlayer connection conductor provided at the substrate. Since the inductor is provided using an interlayer connection conductor provided at the substrate in this configuration, there is no need to separately provide an element. This leads to the ease of manufacturing and the reduction in cost.

In a DC-DC converter module according to a preferred embodiment of the present invention, the first ground end and the shield cover may be electrically connected.

In a DC-DC converter module according to a preferred embodiment of the present invention, the DC-DC converter module further includes a protection member that is provided on a surface of the substrate and covers at least one of the switching-element-incorporating IC, the coil element, and the capacitor element which is disposed on the surface of the substrate. The shield cover is preferably defined by a conductor provided on a surface of the protection member. With this configuration, the coil element and the capacitor element are protected by the protection member. Accordingly, the DC-DC converter module is rugged, and the mechanical strength of the DC-DC converter module and the resistance of the DC-DC converter module to, for example, external forces are increased. With this configuration, as compared with a case in which, for example, the coil element is connected at the substrate by only soldering, the strength of connection of the coil element at the substrate is able to be improved and the reliability of electric connection between the coil element and the substrate is improved.

In a DC-DC converter module according to a preferred embodiment of the present invention, the substrate is preferably a resin substrate and the switching-element-incorporating IC is preferably buried in the substrate. With this configuration, the switching-element-incorporating IC is protected by the substrate. Accordingly, the mechanical strength of the switching-element-incorporating IC and the resistance of the switching-element-incorporating IC to, for example, external forces are increased.

In a DC-DC converter module according to a preferred embodiment of the present invention, the substrate may be a ferrite substrate and the coil element may be defined by a conductor provided at the substrate.

According to preferred embodiments of the present invention, DC-DC converter modules are able to be realized in each of which a shield cover connected to the ground is provided and the flow of noise to the input side or output side thereof is suppressed.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view of a main portion of a DC-DC converter module 101 according to a first preferred embodiment of the present invention.

FIG. 2 is a circuit diagram of the DC-DC converter module 101.

FIG. 3 is a cross-sectional view of a main portion of an electronic apparatus 301 according to the first preferred embodiment of the present invention.

FIG. 4A is a cross-sectional view of a main portion of a DC-DC converter module 102 according to a second preferred embodiment of the present invention, and FIG. 4B is a cross-sectional view taken along the line A-A in FIG. 4A.

FIG. 5 is a circuit diagram of the DC-DC converter module 102.

FIG. 6A is a cross-sectional view of a main portion of a DC-DC converter module 103 according to a third preferred embodiment of the present invention, and FIG. 6B is a cross-sectional view taken along the line B-B in FIG. 6A.

FIG. 7 is a cross-sectional view of a main portion of a DC-DC converter module 104A according to the fourth preferred embodiment of the present invention.

FIG. 8A is a cross-sectional view taken along the line C-C in FIG. 7, and FIG. 8B is a cross-sectional view taken along the line D-D in FIG. 7.

FIG. 9A is a cross-sectional view of a main portion of a DC-DC converter module 104B according to a fourth preferred embodiment of the present invention, and FIG. 9B is a cross-sectional view taken along the line E-E in FIG. 9A.

FIG. 10 is a cross-sectional view of a main portion of a DC-DC converter module 105A according to a fifth preferred embodiment of the present invention.

FIG. 11 is a cross-sectional view of a main portion of another DC-DC converter module 105B according to the fifth preferred embodiment of the present invention.

FIG. 12 is a cross-sectional view of a main portion of a DC-DC converter module 106 according to a sixth preferred embodiment of the present invention.

FIG. 13A is a circuit diagram of a DC-DC converter module 107A according to a seventh preferred embodiment, FIG. 13B is a circuit diagram of another DC-DC converter module 107B according to the seventh preferred embodiment, and FIG. 13C is a circuit diagram of another DC-DC converter module 107C according to the seventh preferred embodiment of the present invention.

### DETAILED DESCRIPTION OF THE PREFERRED EMBODIMENTS

Preferred embodiments of the present invention will be described below with reference to the drawings. The same or similar elements and components are denoted by the same reference symbols in the drawings. While the preferred embodiments are described separately for the sake of convenience in consideration of ease of explanation and understanding of key points, configurations described in the different preferred embodiments may be partially replaced or combined. In the second and subsequent preferred embodiments, descriptions of structural elements or portions common to those in the first preferred embodiment will be omitted and only different structure will be described. In particular, descriptions of similar advantageous effects obtained with similar configurations will not be repeated in each of the preferred embodiments.

### First Preferred Embodiment

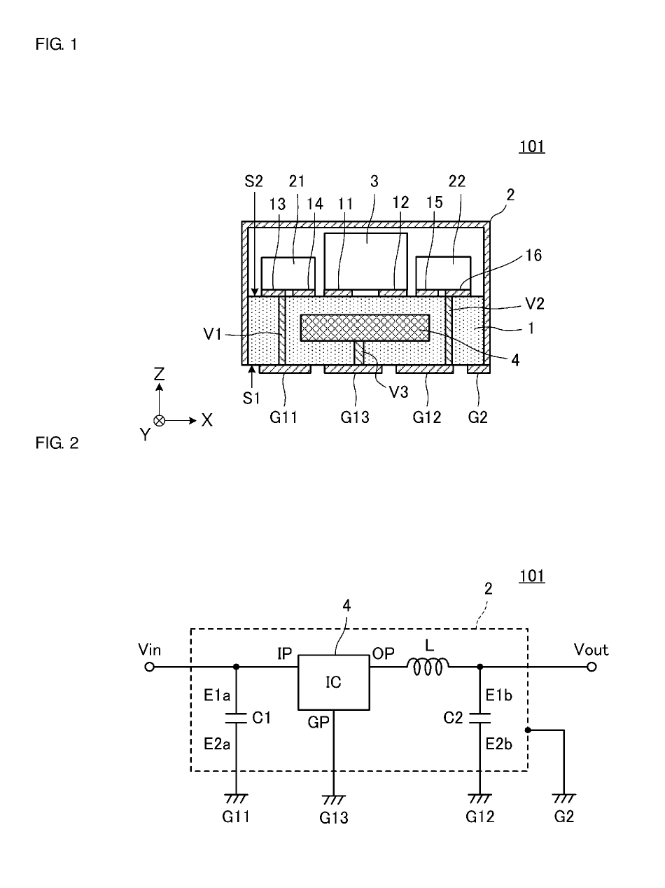

FIG. 1 is a cross-sectional view of a main portion of a DC-DC converter module 101 according to a first preferred embodiment of the present invention.

The DC-DC converter module 101 includes, for example, a substrate 1, first ground electrodes G11, G12, and G13, a second ground electrode G2, a coil element 3, capacitor elements 21 and 22, a switching-element-incorporating IC 4, and a shield cover 2.

The substrate 1 is preferably a rectangular or substantially rectangular parallelepiped insulating plate including a first main surface S1 and a second main surface S2. The substrate 1 is preferably a thermoplastic resin substrate (sheet) made of, for example, polyimide (PI) or liquid-crystal polymer (LCP).

The first ground electrodes G11, G12, and G13 and the second ground electrode G2 are conductors provided on the first main surface S1 of the substrate 1. On the second main surface S2 of the substrate 1, conductors 11, 12, 13, 14, 15 and 16 are provided. The conductor 13 is connected to the first ground electrode G11 via an interlayer connection conductor V1 provided in the substrate 1. The conductor 16 is connected to the first ground electrode G12 via an interlayer connection conductor V2 provided in the substrate 1. The first ground electrodes G11, G12, and G13, the second ground electrode G2, and the conductors 11, 12, 13, 14, 15, and 16 are preferably conductive patterns made of, for example, Cu foil.

The switching-element-incorporating IC 4 is buried in the substrate 1. As will be described later, the switching-element-incorporating IC 4 includes an input end, an output end, and a first ground end and incorporates a switching element to switch a current flowing through the coil element 3. The first ground end of the switching-element-incorporating IC 4 is connected to the first ground electrode G13 via an interlayer connection conductor V3 provided in the substrate 1. The switching-element-incorporating IC is preferably, for example, a microprocessor chip or an IC chip. The switching-element-incorporating IC 4 is buried in the substrate 1 such that a cavity is provided in a multilayer body including a plurality of insulating substrate layers preferably made of, for example, a thermoplastic resin and the multilayer body including the switching-element-incorporating IC 4 in the cavity is heated and pressurized.

The coil element 3 and the capacitor elements 21 and 22 are disposed on the second main surface S2 of the substrate 1. The coil element 3 and the capacitor elements 21 and 22 are disposed on the second main surface S2 via a conductive joining material, such as solder, for example. More specifically, the coil element 3 is joined (connected) between the conductors 11 and 12, the capacitor element 21 is joined (connected) between the conductors 13 and 14, and the capacitor element 22 is joined (connected) between the conductors 15 and 16. The coil element 3 is preferably, for example, a chip inductor. The capacitor element 21 is an input capacitor and the capacitor element 22 is an output capacitor. The capacitor elements 21 and 22 are preferably, for example, chip capacitors.

The shield cover 2 is a metal cover that covers the coil element 3 and the capacitor elements 21 and 22 which are disposed on the second main surface S2 of the substrate 1. As illustrated in FIG. 1, the shield cover 2 is connected to the second ground electrode G2 provided on the first main surface S1 of the substrate 1.

FIG. 2 is a circuit diagram of the DC-DC converter module 101. In FIG. 2, the coil element 3 is represented by a coil L, the capacitor element 21 is represented by an input capacitor C1, and the capacitor element 22 is represented by an output capacitor C2. The illustration of a voltage input portion Vin and a voltage output portion Vout in FIG. 2 is omitted in FIG. 1.

The switching-element-incorporating IC4 and the coil L are connected between the voltage input portion Vin that receives a DC voltage and the voltage output portion Vout. The switching-element-incorporating IC4 incorporates an element to switch a current flowing through the coil L. The switching-element-incorporating IC4 is connected to each of the voltage input portion Vin, the coil L, and the first ground electrode G13. The coil L is connected between the switching-element-incorporating IC4 and the voltage output portion Vout. The input capacitor C1 is connected between the voltage input portion Vin and the first ground electrode G11. The output capacitor C2 is connected between the voltage output portion Vout and the first ground electrode G12. The shield cover 2 is connected to the second ground electrode G2.

Specifically, an input end IP of the switching-element-incorporating IC4 is connected to the voltage input portion Vin. A first ground end GP of the switching-element-incorporating IC4 is connected to the first ground electrode G13. An output end OP of the switching-element-incorporating IC4 is connected to a first end of the coil L. A second end of the coil L is connected to the voltage output portion Vout. A first end E1a of the input capacitor C1 is connected to the voltage input portion Vin, and a second end E2a of the input capacitor C1 is connected to the first ground electrode G11. A first end E1b of the output capacitor C2 is connected to the voltage output portion Vout, and a second end E2b of the output capacitor C2 is connected to the first ground electrode G12. The shield cover 2 is connected to the second ground electrode G2.

Thus, the DC-DC converter module 101 is a step-down DC-DC converter module.

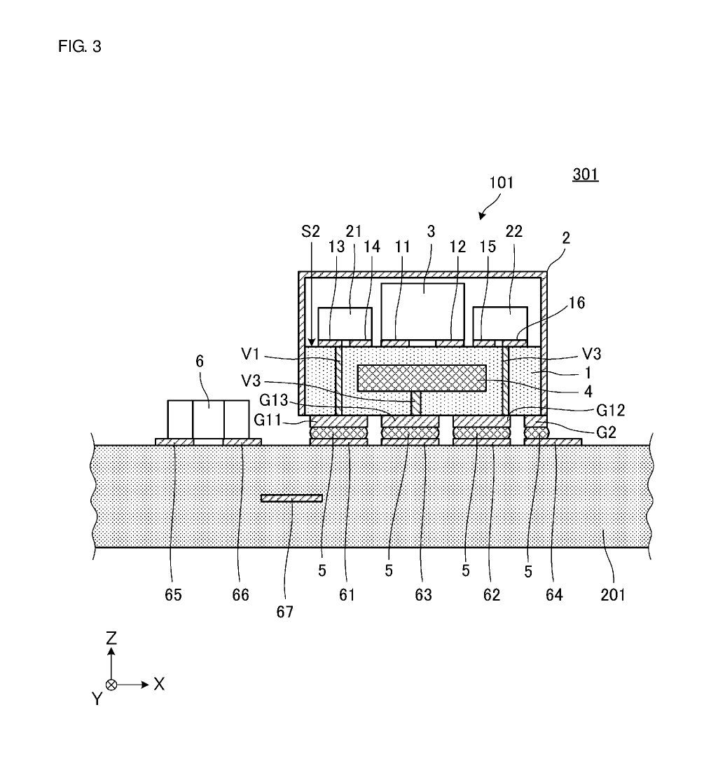

Next, a state in which the DC-DC converter module 101 is disposed on a mounting board using a conductive joining material will be described with reference to a drawing. FIG. 3 is a cross-sectional view of a main portion of an electronic apparatus 301 according to the first preferred embodiment.

The electronic apparatus 301 includes, for example, a DC-DC converter module and a mounting board and is preferably, for example, a cellular phone terminal, a so-called smartphone, a tablet terminal, a notebook PC, a PDA, a wearable terminal (for example, a so-called smart watch or so-called smart glasses), a camera, a game machine, or a toy.

The electronic apparatus 301 includes, for example, the DC-DC converter module 101, a mounting board 201, and a surface-mount component 6. The mounting board 201 is preferably, for example, a printed-circuit board.

On the main surface of the mounting board 201, the DC-DC converter module 101 and the surface-mount component 6 are disposed. The surface-mount component 6 is preferably, for example, a chip inductor.

On the main surface of the mounting board 201, conductors 61, 62, 63, 64, 65, and 66 are provided. In the mounting board 201, a conductor 67 is provided. The first ground electrode G11 is connected to the conductor 61 via a conductive joining material 5. The first ground electrode G12 is connected to the conductor via the conductive joining material 5. The first ground electrode G13 is connected to the conductor 63 via the conductive joining material 5. The second ground electrode G2 is connected to the conductor 64 via the conductive joining material 5. A voltage input portion (not illustrated) and a voltage output portion (not illustrated) of the DC-DC converter module are connected to a conductor (not illustrated) provided at the mounting board 201. The conductive joining material 5 is preferably, for example, solder. The conductors 61, 62, 63, and 64 are connected to different grounds of the mounting board 201. The conductors 65 and 66 are connected to respective circuits provided at the mounting board 201.

Using the DC-DC converter module 101 according to the present preferred embodiment, the following advantageous effects are obtained.

The DC-DC converter module 101 has a configuration in which the coil element 3 and the capacitor elements 21 and 22 disposed on the second main surface S2 of the substrate 1 are covered with the shield cover 2. With this configuration, noise that is caused by switching and is emitted from, for example, the coil element 3 or the switching-element-incorporating IC is shielded by the shield cover 2. Accordingly, noise emitted from the DC-DC converter module is reduced or prevented.

In the present preferred embodiment, the shield cover 2 is connected to the second ground electrode G2 that is different from the first ground electrodes G11 and G12 to which the capacitor elements 21 and 22 are connected, respectively. In this configuration, the shield cover 2 and each of the capacitor elements 21 and 22, which are connected to the respective grounds, are separated from one another. Accordingly, the flow of noise induced by the shield cover 2 (switching noise that is emitted from, for example, the coil element 3 or the switching-element-incorporating IC 4 and is shielded by the shield cover 2) to the input side or output side of the DC-DC converter module via the capacitor elements 21 and 22 is reduced or prevented. A DC-DC converter module in which the flow of noise to the input side or the output side thereof is reduced or prevented is provided.

In the present preferred embodiment, the switching-element-incorporating IC 4 is buried in the substrate 1. With this configuration, the switching-element-incorporating IC 4 is protected by the substrate 1. Accordingly, the mechanical strength of the switching-element-incorporating IC 4 and the resistance of the switching-element-incorporating IC 4 to, for example, external forces are increased.

### Second Preferred Embodiment

In a second preferred embodiment of the present invention, an exemplary case in which the first ground end of a switching-element-incorporating IC is electrically connected to a shield cover will be described.

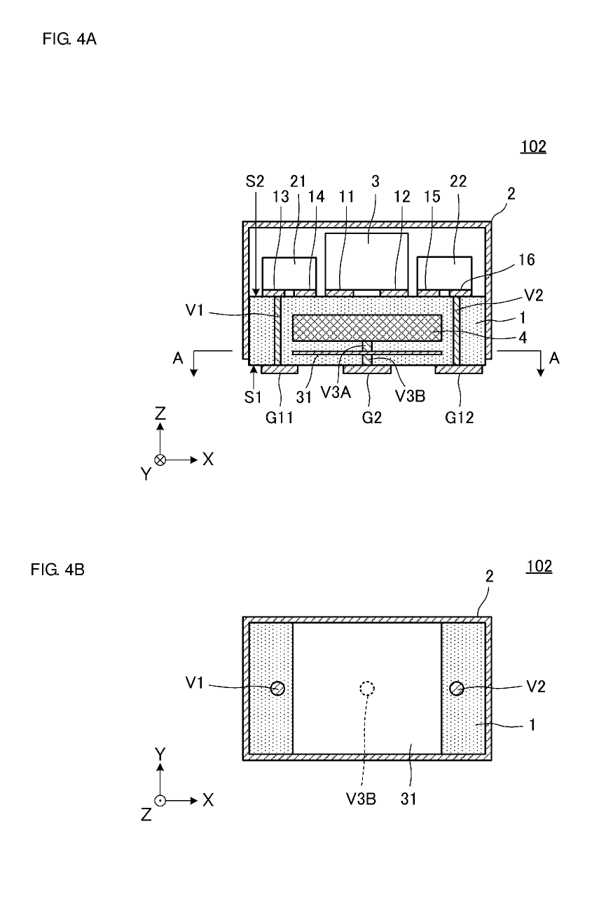

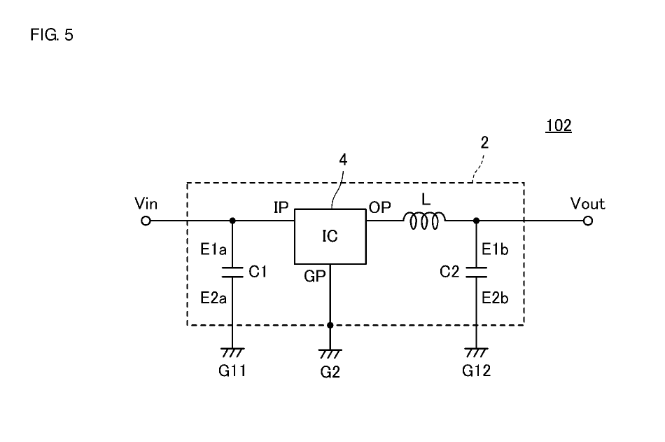

FIG. 4A is a cross-sectional view of a main portion of a DC-DC converter module 102 according to the second preferred embodiment, and FIG. 4B is a cross-sectional view taken along the line A-A in FIG. 4A. FIG. 5 is a circuit diagram of the DC-DC converter module 102.

The DC-DC converter module 102 includes, for example, the substrate 1, the first ground electrodes G11 and G12, the second ground electrode G2, the coil element 3, the capacitor elements 21 and 22, the switching-element-incorporating IC 4, and the shield cover 2.

The DC-DC converter module 102 differs from the DC-DC converter module 101 according to the first preferred embodiment in that a ground conductor 31 is provided in the substrate 1. The remaining configuration is the same or substantially the same as that of the DC-DC converter module 101. A configuration different from a configuration according to the first preferred embodiment will be described below.

The ground conductor 31 is preferably a rectangular or substantially rectangular conductive pattern provided in the substrate 1 as illustrated in FIG. 4B. The ground conductor 31 is preferably made of, for example, Cu foil.

A portion of the ground conductor 31 (the top side and bottom side of the ground conductor 31 in FIG. 4B) is exposed at the end surfaces of the substrate 1 and is connected to the shield cover 2. As illustrated in FIG. 4A, the ground conductor 31 is connected to the first ground end of the switching-element-incorporating IC 4 via the interlayer connection conductor V3A provided in the substrate 1. The ground conductor 31 is connected to the second ground electrode G2 via the interlayer connection conductor V3B provided in the substrate 1.

That is, as illustrated in FIG. 5, the first ground end GP of the switching-element-incorporating IC 4 and the shield cover are connected to the second ground electrode G2 and are electrically connected to each other.

With this configuration, the flow of noise induced by the shield cover 2 (switching noise that is emitted from, for example, the coil element 3 or the switching-element-incorporating IC 4 and is shielded by the shield cover 2) to the input side or output side of the DC-DC converter module via the capacitor elements 21 and 22 rarely occurs as compared with a case in which the shield cover 2 is electrically connected to the second ends of the capacitor elements 21 and 22. Accordingly, the first ground end GP of the switching-element-incorporating IC 4 and the shield cover 2 may be electrically connected to each other as in the present preferred embodiment.

### Third Preferred Embodiment

In a third preferred embodiment of the present invention, an exemplary case in which a capacitor element and a shield cover are physically connected will be described.

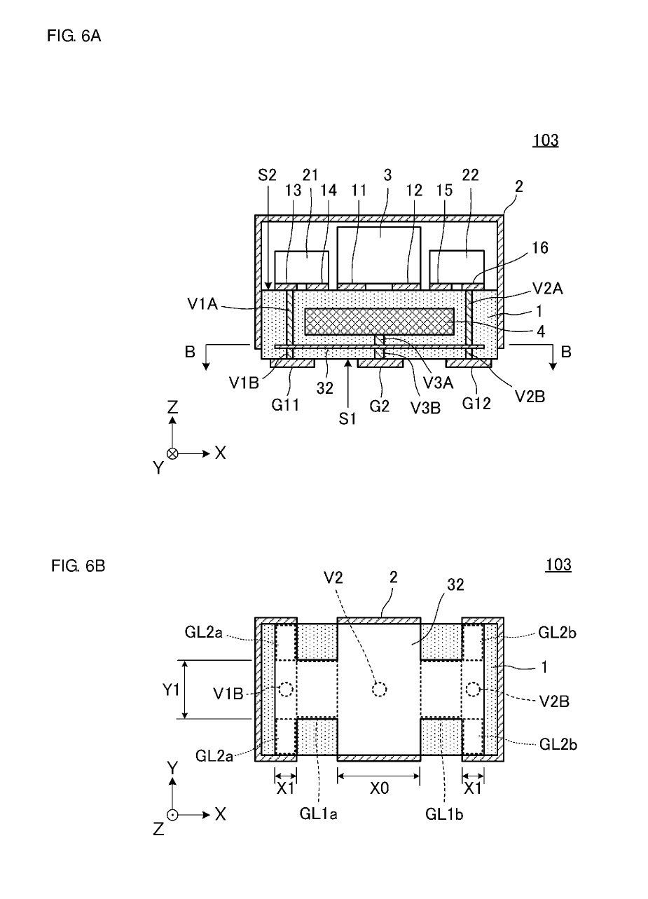

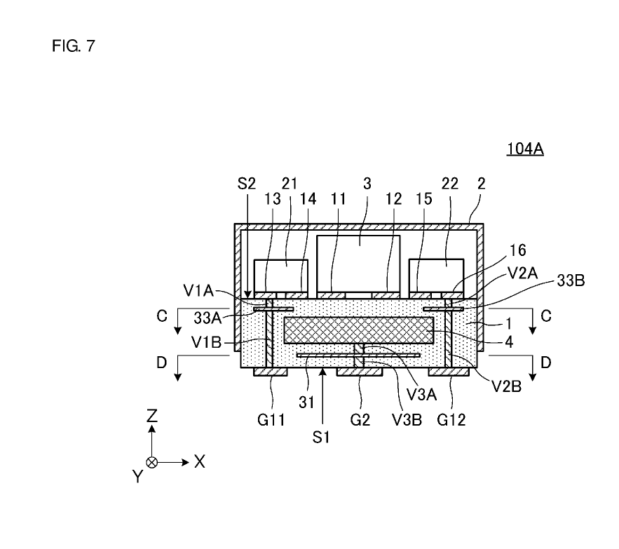

FIG. 6A is a cross-sectional view of a main portion of a DC-DC converter module 103 according to the third preferred embodiment, and FIG. 6B is a cross-sectional view taken along the line B-B in FIG. 6A. FIG. 7 is a cross-sectional view of a main portion of a DC-DC converter module 104A according to the fourth preferred embodiment.

The DC-DC converter module 103 differs from the DC-DC converter module 102 according to the second preferred embodiment in that a ground conductor 32 is provided in the substrate 1. The remaining configuration is the same or substantially the same as that of the DC-DC converter module 102. A configuration different from a configuration according to the second preferred embodiment will be described below.

The ground conductor 32 is a conductive pattern provided in the substrate 1. A portion of the ground conductor 32 (portions of the top side and bottom side of the ground conductor 32 in FIG. 6B) is exposed at the end surfaces of the substrate 1 and is connected to the shield cover 2. As illustrated in FIG. 6A, the ground conductor 32 is connected to the first ground end of the switching-element-incorporating IC 4 and the second ends of the capacitor elements 21 and 22 via the interlayer connection conductors V1A, V2A, and V3A provided in the substrate 1. The ground conductor 32 is connected to the first ground electrodes G11 and G12 and the second ground electrode G2 via the interlayer connection conductors V1B, V2B, and V3B provided in the substrate 1, respectively.

That is, the first ground end of the switching-element-incorporating IC 4, the second ends of the capacitor elements 21 and 22, and the shield cover 2 are physically connected.

The ground conductor 32 includes narrow-width portions GL1a, GL1b, GL2a and GL2b as illustrated in FIG. 6B. The narrow-width portion GL1a has a narrow conductor width (a conductor width Y1) that is provided at an electric path between the second ground electrode G2 and the first ground electrode G11. The narrow-width portion GL1b has a narrow conductor width (the conductor width Y1) that is provided at an electric path between the second ground electrode G2 and the first ground electrode G12. The narrow-width portion GL2a has a narrow conductor width (a conductor width X1) that is provided at an electric path between the first ground electrode G11 and the shield cover 2. The narrow-width portion GL2b has a narrow conductor width (the conductor width X1) that is provided at an electric path between the first ground electrode G12 and the shield cover 2. The conductor widths of the narrow-width portions GL1a, GL1b, GL2a, and GL2b are relatively narrower than a conductor width X0 of the other portion (X0>X1, X0>Y1).

The narrow-width portions GL1a, GL1b, GL2a, and GL2b are electrically disconnected at a frequency higher than or equal to a predetermined frequency. Specifically, the conductor widths and conductor lengths of the narrow-width portions GL1a, GL1b, GL2a, and GL2b are set such that a predetermined inductance component is provided at a predetermined frequency. Accordingly, between each of the second ends of the capacitor elements 21 and 22 and the shield cover 2, an inductor (the narrow-width portions GL1a, GL1b, GL2a, and GL2b) that has a predetermined inductance component at a predetermined frequency is connected.

A “predetermined frequency” is determined in accordance with the switching frequency of the switching-element-incorporating IC 4. A “predetermined inductance component” varies in accordance with the above-described “predetermined frequency”. For example, the “predetermined inductance component” preferably has an inductance value less than or equal to about 5 μH when the “predetermined frequency” is greater than or equal to about 1 MHz and is less than about 100 MHz, has an inductance value less than or equal to about 5 nH when the “predetermined frequency” is greater than or equal to about 100 MHz and is less than about 1 GHz, and has an inductance value less than or equal to about 0.5 nH when the “predetermined frequency” is greater than or equal to 1 GHz and is less than or equal to about 2 GHz.

With the DC-DC converter module 103 according to the present preferred embodiment, the following advantageous effects are obtained.

In the present preferred embodiment, each of the second ends of the capacitor elements 21 and 22 and the shield cover 2 are electrically disconnected at a frequency higher than or equal to the predetermined frequency. Even if each of the capacitor elements 21 and 22 and the shield cover 2 are physically connected, the shield cover 2 is connected at a frequency higher than or equal to the predetermined frequency to the second ground electrode G2 that is electrically different from the first ground electrodes G11 and G12 to which the capacitor elements 21 and 22 are connected, respectively. Accordingly, as in the first preferred embodiment, the flow of noise induced by the shield cover to the input side or output side of the DC-DC converter module is reduced or prevented. The DC-DC converter module in which the flow of noise to the input side or output side thereof is reduced or prevented is therefore achieved.

In the present preferred embodiment, the first ground end of the switching-element-incorporating IC 4 and each of the second ends of the capacitor elements 21 and 22 are physically connected via, for example, the ground conductor 32. With this configuration, a direct-current electric path between the first ground end of the switching-element-incorporating IC 4 and each of the second ends of the capacitor elements 21 and 22 is short. Accordingly, as compared with a case in which the first ground end of the switching-element-incorporating IC4 and the second ends of the capacitor elements 21 and 22 are connected to different grounds, the power conversion efficiency of the DC-DC converter module is improved.

In the present preferred embodiment, since an inductor is structured using the ground conductor 32 (conductive pattern) provided at the substrate 1, there is no need to separately provide an element. This facilitates manufacturing and reduces cost.

### Fourth Preferred Embodiment

In a fourth preferred embodiment of the present invention, an exemplary configuration in which a capacitor element and a shield cover are physically connected and which is different from a configuration according to the third preferred embodiment will be described.

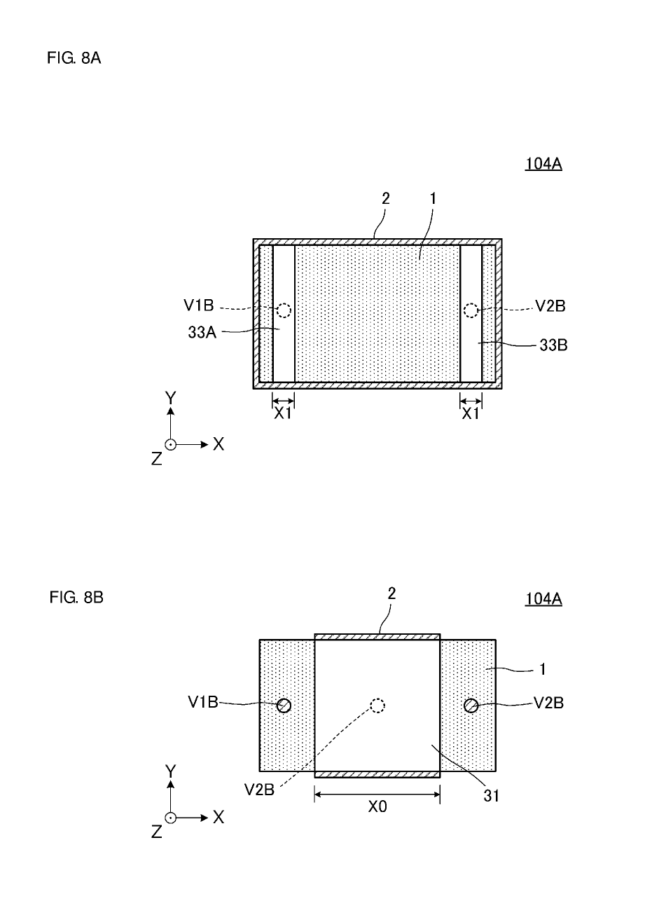

FIG. 7 is a cross-sectional view of a main portion of a DC-DC converter module 104A according to the fourth preferred embodiment. FIG. 8A is a cross-sectional view taken along the line C-C in FIG. 7, and FIG. 8B is a cross-sectional view taken along the line D-D in FIG. 7.

The DC-DC converter module 104A differs from the DC-DC converter module 102 according to the second preferred embodiment in that ground conductors 33A and 33B are provided in the substrate 1. The remaining configuration is the same or substantially the same as that of the DC-DC converter module 102. A configuration different from a configuration according to the second preferred embodiment will be described below.

The ground conductors 33A and 33B are preferably rectangular or substantially rectangular conductive patterns and provided in the substrate 1. A portion of the ground conductor 33A (the top side and bottom side of the ground conductor 33A in FIG. 8A) is exposed at the end surfaces of the substrate 1 and is connected to the shield cover 2. The ground conductor 33A is connected to the second end of the capacitor element 21 and the first ground electrode G11 via the interlayer connection conductors V1A and V1B provided in the substrate 1, respectively as illustrated in FIG. 7. A portion of the ground conductor 33B (the top side and bottom side of the ground conductor 33B in FIG. 8A) is exposed at the end surfaces of the substrate 1 and is connected to the shield cover 2. The ground conductor 33B is connected to the second end of the capacitor element 22 and the first ground electrode G12 via the interlayer connection conductors V2A and V2B provided in the substrate 1, respectively.

That is, each of the second ends of the capacitor elements 21 and 22 and the shield cover 2 are physically connected.

As illustrated in FIG. 8A, in the ground conductor 33A, the conductor width X1 of an electric path between the first ground electrode G11 and the shield cover 2 is relatively narrower than the conductor width of an electric path between the second ground electrode G2 and the shield cover 2 (the conductor width X0 of the ground conductor 31) (X0>X1). In the ground conductor 33B, the conductor width X1 of an electric path between the first ground electrode G12 and the shield cover 2 is relatively narrower than the conductor width of an electric path between the second ground electrode G2 and the shield cover 2 (the conductor width X0 of the ground conductor 31) (X0>X1).

Accordingly, an inductor that has a predetermined inductance component at a predetermined frequency is connected between each of the second ends of the capacitor elements 21 and 22 and the shield cover 2.

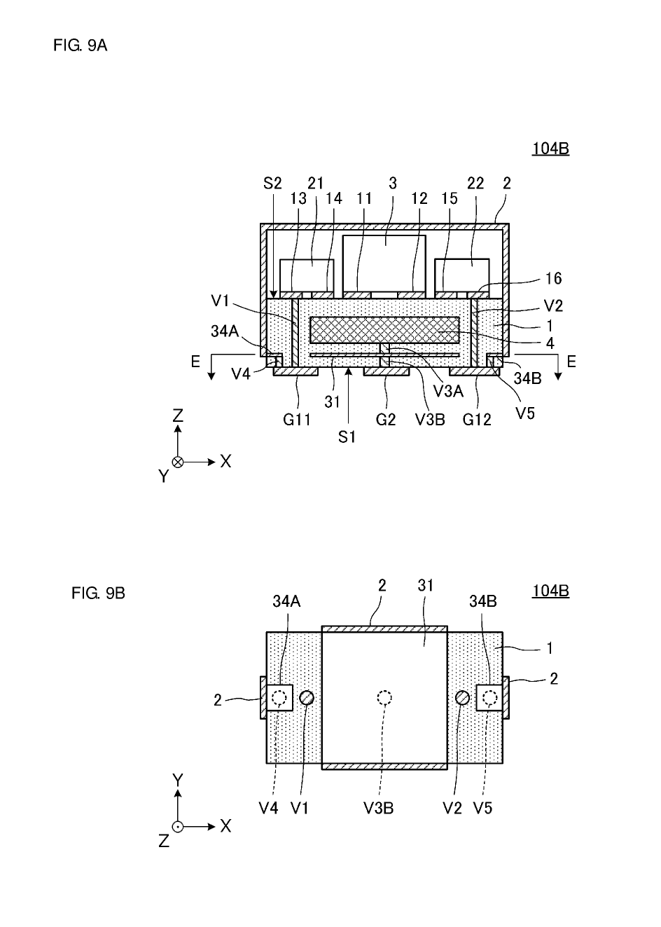

Next, another DC-DC converter module according to the present preferred embodiment will be described. FIG. 9A is a cross-sectional view of a main portion of another DC-DC converter module 104B according to the fourth preferred embodiment, and FIG. 9B is a cross-sectional view taken along the line E-E in FIG. 9A.

The DC-DC converter module 104B differs from the DC-DC converter module 102 according to the second preferred embodiment in that ground conductors 34A and 34B and interlayer connection conductors V4 and V5 are provided in the substrate 1. The remaining configuration is the same or substantially the same as that of the DC-DC converter module 102. A configuration different from a configuration according to the second preferred embodiment will be described below.

The ground conductors 34A and 34B are preferably rectangular or substantially rectangular conductive patterns provided in the substrate 1. A portion of the ground conductor 34A (the left side of the ground conductor 34A in FIG. 9B) is exposed at the end surface of the substrate 1 and is connected to the shield cover 2. The ground conductor 34A is connected to the first ground electrode G11 via the interlayer connection conductor V4 provided in the substrate 1 as illustrated in FIG. 9A. A portion of the ground conductor 34B (the right side of the ground conductor 34B in FIG. 9B) is exposed at the end surface of the substrate 1 and is connected to the shield cover 2. The ground conductor 34B is connected to the first ground electrode G12 via the interlayer connection conductor V5 provided in the substrate 1.

That is, each of the second ends of the capacitor elements 21 and 22 and the shield cover 2 are physically connected.

In the present preferred embodiment, the conductor diameters and conductor lengths of the interlayer connection conductors V4 and V5 are set such that a predetermined inductance component is provided at a predetermined frequency. Accordingly, between each of the second ends of the capacitor elements 21 and 22 and the shield cover 2, an inductor that has a predetermined inductance component at a predetermined frequency is connected.

### Fifth Preferred Embodiment

In a fifth preferred embodiment of the present invention, an example of a DC-DC converter module in which a switching-element-incorporating IC is disposed on the surface of a substrate will be described.

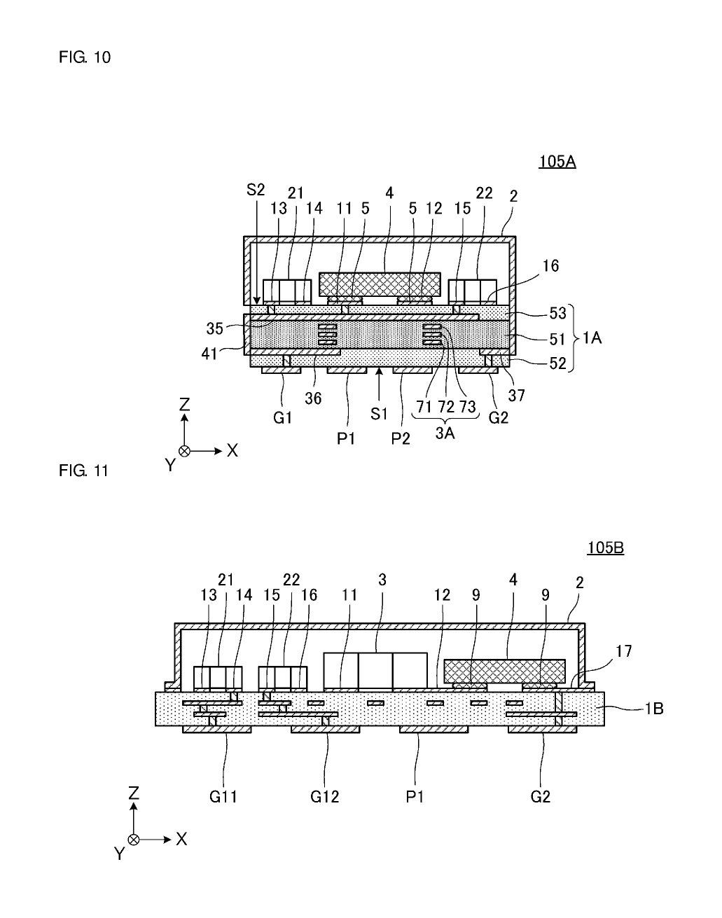

FIG. 10 is a cross-sectional view of a main portion of a DC-DC converter module 105A according to the fifth preferred embodiment.

The DC-DC converter module 105A includes, for example, a substrate 1A, mounting electrodes P1 and P2, a first ground electrode G1, the second ground electrode G2, a coil 3A, the capacitor elements 21 and 22, the switching-element-incorporating IC 4, and the shield cover 2.

The DC-DC converter module 105A differs from the DC-DC converter module 101 according to the first preferred embodiment in that it includes the substrate 1A. In addition, the DC-DC converter module 105A differs from the DC-DC converter module 101 in that the switching-element-incorporating IC 4 is disposed on the second main surface S2 of the substrate 1A. A configuration different from a configuration according to the first preferred embodiment will be described.

The substrate 1A is a multilayer body including a magnetic substance layer 51 and non-magnetic substance layers 52 and 53, and is preferably a rectangular or substantially rectangular parallelepiped insulating plate including the first main surface S1 and the second main surface S2. In the substrate 1A, the magnetic substance layer 51 is sandwiched between the non-magnetic substance layers 52 and 53. The substrate 1A is preferably, for example, a ferrite substrate. The magnetic substance layer 51 is preferably, for example, a magnetic substance ferrite sheet. The non-magnetic substance layers 52 and 53 are non-magnetic substance ferrite sheets.

The mounting electrodes P1 and P2, the first ground electrode G1, and the second ground electrode G2 are conductors provided on the first main surface S1 of the substrate 1A. On the second main surface S2 of the substrate 1A, the conductors 11, 12, 13, 14, 15, and 16 are provided. Each of the conductors 11, 13, and 15 are connected to a ground conductor 35 provided at the non-magnetic substance layer 53 via an interlayer connection conductor. The ground conductor 35 is connected to one end of an end-surface conductor 41 provided at the end surface of the magnetic substance layer 51. The other end of the end-surface conductor 41 is connected to a ground conductor 36 provided at the non-magnetic substance layer 52. The ground conductor 36 is connected to the first ground electrode G1 via an interlayer connection conductor.

The switching-element-incorporating IC 4 and the capacitor elements 21 and 22 are disposed on the second main surface S2 of the substrate 1A. The switching-element-incorporating IC 4, and the capacitor elements 21 and 22 are disposed on the second main surface S2 via the conductive joining material 5, such as solder, for example. More specifically, the switching-element-incorporating IC 4 is joined (connected) between the conductors 11 and 12, the capacitor element 21 is joined (connected) between the conductors 13 and 14, and the capacitor element 22 is joined (connected) between the conductors 15 and 16. Accordingly, the first ground end of the switching-element-incorporating IC4 and the second ends of the capacitor elements 21 and 22 are connected to the first ground electrode G1.

The coil 3A is preferably a helical coil including coil conductors 71, 72, and 73 provided in the magnetic substance layer 51. The coil conductors 71, 72, and 73 are preferably loop or spiral conductive patterns.

The shield cover 2 is a metal cover that covers, for example, the switching-element-incorporating IC 4 and the capacitor elements 21 and 22 disposed on the second main surface S2 of the substrate 1A. The shield cover 2 is connected to the second ground electrode G2 via a ground conductor 37 and an interlayer connection conductor which are provided in the substrate 1A.

As described in the present preferred embodiment, the switching-element-incorporating IC 4 may be disposed on the surface of the substrate 1A. As described in the present preferred embodiment, a coil may be defined by conductors provided in the substrate 1A. As described in the present preferred embodiment, a DC-DC converter module may include a mounting electrode other than a ground electrode.

Next, another example of a DC-DC converter module according to the present preferred embodiment will be described. FIG. 11 is a cross-sectional view of a main portion of another DC-DC converter module 105B according to the fifth preferred embodiment.

The DC-DC converter module 105B includes, for example, a substrate 1B, a mounting electrode P1, the first ground electrodes G11 and G12, the second ground electrode G2, the coil element 3, the capacitor elements 21 and 22, the switching-element-incorporating IC 4, and the shield cover 2.

The DC-DC converter module 105B differs from the DC-DC converter module 101 according to the first preferred embodiment in that it includes the substrate 1B. The DC-DC converter module 105B differs from the DC-DC converter module 101 in that the switching-element-incorporating IC 4 is disposed on the second main surface S2 of the substrate 1B. A configuration different from a configuration according to the first preferred embodiment will be described below.

The substrate 1B is preferably a rectangular or substantially rectangular parallelepiped insulating plate including the first main surface S1 and the second main surface S2. The substrate 1B is preferably, for example, a printed-circuit board.

The mounting electrode P1, the first ground electrodes G11 and G12, and the second ground electrode G2 are conductors provided on the first main surface S1 of the substrate 1B. On the second main surface S2 of the substrate 1A, the conductors 11, 12, 13, 14, 15, 16 and 17 are provided. The conductor 14 is connected to the first ground electrode G11 via another conductor and an interlayer connection conductor. The conductor 15 is connected to the first ground electrode G12 via another conductor and an interlayer connection conductor. A conductor 17 is connected to the second ground electrode G2 via another conductor and an interlayer connection conductor.

The switching-element-incorporating IC 4, the coil element 3, and the capacitor elements 21 and 22 are disposed on the second main surface S2 of the substrate 1B. The switching-element-incorporating IC 4, the coil element 3, and the capacitor elements 21 and 22 are disposed on the second main surface S2 via the conductive joining material 5, such as solder, for example. More specifically, the coil element 3 is joined (connected) between the conductors 11 and 12, the switching-element-incorporating IC is joined (connected) between the conductors 12 and 17, the capacitor element 21 is joined (connected) between the conductors 13 and 14, and the capacitor element 22 is joined (connected) between the conductors 15 and 16. Accordingly, the second end of the capacitor element 21 is connected to the first ground electrode G11, and the second end of the capacitor element 22 is connected to the first ground electrode G12. The first ground end of the switching-element-incorporating IC4 is connected to the second ground electrode G2.

The shield cover 2 is a metal cover that is disposed on the second main surface S2 of the substrate 1B and covers, for example, the switching-element-incorporating IC 4, the coil element 3, and the capacitor elements 21 and 22. The outer edge of the shield cover 2 is joined via, for example, a conductive joining material to be electrically connected to the conductor 17 formed on the second main surface S2 of the substrate 1B. The shield cover 2 is therefore connected to the second ground electrode G2. The first ground end of the switching-element-incorporating IC4 and the shield cover 2 are electrically connected.

### Sixth Preferred Embodiment

In a sixth preferred embodiment of the present invention, an exemplary case in which the configuration of a shield cover differs from that of shield covers in the other configurations will be described.

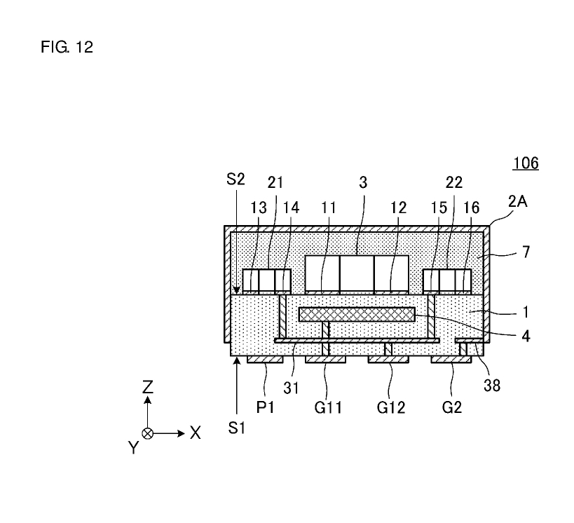

FIG. 12 is a cross-sectional view of a main portion of a DC-DC converter module 106 according to the sixth preferred embodiment.

The DC-DC converter module 106 includes, for example, the substrate 1, the mounting electrode P1, the first ground electrodes G11 and G12, the second ground electrode G2, the coil element 3, the capacitor elements 21 and 22, the switching-element-incorporating IC 4, a protection member 7, and a shield cover 2A.

The DC-DC converter module 106 differs from the DC-DC converter module 102 according to the second preferred embodiment in that it includes the protection member 7. The DC-DC converter module 106 is different in the configuration of the shield cover 2A from the DC-DC converter module 102. A configuration different from a configuration according to the second preferred embodiment will be described below.

The mounting electrode P1, the first ground electrodes G11 and G12, and the second ground electrode G2 are conductors provided on the first main surface S1 of the substrate 1. On the second main surface S2 of the substrate 1, the conductors 11, 12, 13, 14, 15, and 16 are provided. Each of the conductors 14 and 15 is connected to the ground conductor 31 provided in the substrate 1 via an interlayer connection conductor. The ground conductor 31 is connected to the first ground electrodes G11 and G12 via interlayer connection conductors.

The switching-element-incorporating IC 4 is buried in the substrate 1. The first ground end of the switching-element-incorporating IC4 is connected to the ground conductor 31 via an interlayer connection conductor.

The coil element 3 and the capacitor elements 21 and 22 are disposed on the second main surface S2 of the substrate 1. The coil element 3 and the capacitor elements 21 and 22 are disposed on the second main surface S2 via a conductive joining material, such as solder, for example. More specifically, the coil element 3 is joined (connected) between the conductors 11 and 12, the capacitor element 21 is joined (connected) between the conductors 13 and 14, and the capacitor element 22 is joined (connected) between the conductors 15 and 16. Accordingly, the first ground end of the switching-element-incorporating IC4 and the second ends of the capacitor elements 21 and 22 are connected to the first ground electrodes G11 and G12.

The protection member 7 is a block that is provided on the second main surface S2 of the substrate 1 and covers the coil element 3 and the capacitor elements 21 and 22 disposed (mounted) on the second main surface S2. That is, the coil element 3 and the capacitor elements 21 and 22 are buried in the protection member 7 provided on the second main surface S2 of the substrate 1. The protection member 7 is preferably, for example, a thermosetting resin such as an epoxy resin.

The shield cover 2A is a conductor provided on the surface of the protection member 7 and a portion of the substrate (end surfaces). The shield cover 2A is a conductive pattern that covers, for example, the coil element 3 and the capacitor elements 21 and 22. The shield cover 2A is connected to the second ground electrode G2 via a ground conductor 38 and an interlayer connection conductor which are provided in the substrate 1. The shield cover 2A is a metal film obtained by performing, for example, printing or sputtering using a conductive material upon the surface of the protection member 7.

In the present preferred embodiment, the coil element 3 and the capacitor elements 21 and 22 disposed (mounted) on the second main surface S2 of the substrate 1 are covered (sealed) with the protection member 7. With this configuration, the coil element 3 and the capacitor elements 21 and 22 are protected by the protection member 7. Accordingly, the DC-DC converter module is rugged, and the mechanical strength of the DC-DC converter module and the resistance of the DC-DC converter module to, for example, external forces are increased. With this configuration, as compared with a case in which, for example, the coil element 3 is disposed at the substrate 1 by only soldering, the strength of connection of the coil element at the substrate 1 is improved and the reliability of electric connection between the coil element and the substrate is improved.

### Seventh Preferred Embodiment

In a seventh preferred embodiment of the present invention, an exemplary case in which a circuit configuration differs from that of the DC-DC converter module 101 according to the first preferred embodiment will be described.

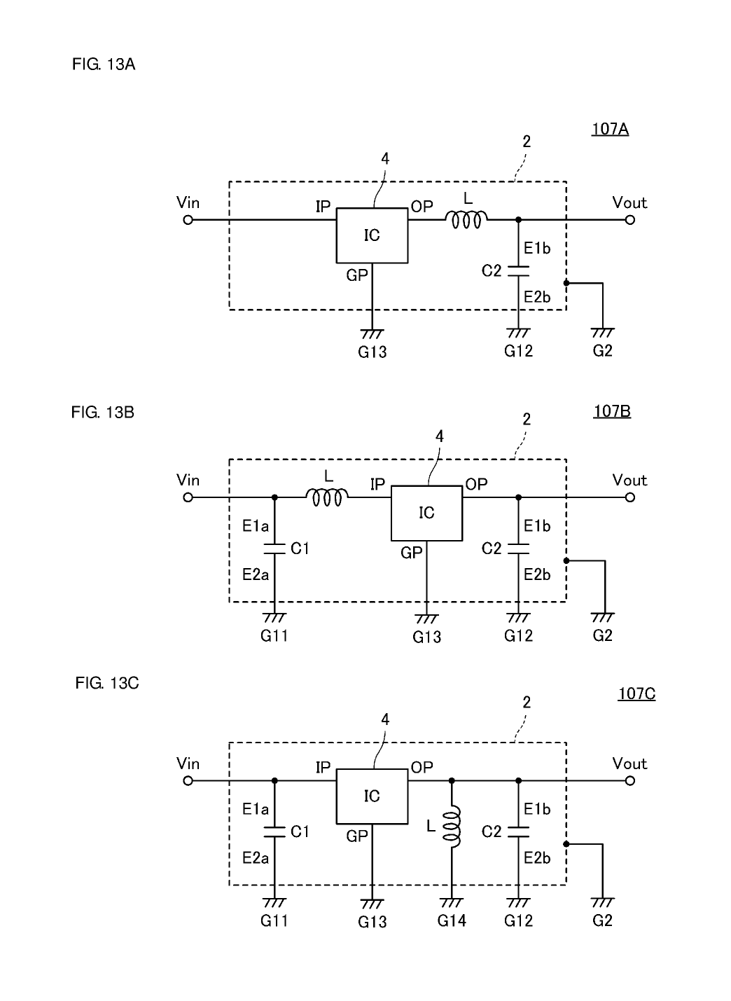

FIG. 13A is a circuit diagram of a DC-DC converter module 107A according to the seventh preferred embodiment, FIG. 13B is a circuit diagram of another DC-DC converter module 107B according to the seventh preferred embodiment, and FIG. 13C is a circuit diagram of another DC-DC converter module 107C according to the seventh preferred embodiment.

The DC-DC converter module 107A illustrated in FIG. 13A differs from the DC-DC converter module 101 according to the first preferred embodiment in that it does not include the first ground electrode G11 and the input capacitor C1. The remaining configuration is the same or substantially the same as that of the DC-DC converter module 101 illustrated in FIG. 2.

As described in the present preferred embodiment, a DC-DC converter module may include only the output capacitor C2. Alternatively, a DC-DC converter module according to a preferred embodiment of the present invention may include only an input capacitor.

The DC-DC converter module 107B illustrated in FIG. 13B is an example of a step-up DC-DC converter module. The basic configuration of the DC-DC converter module 107B is the same or substantially the same as that of the DC-DC converter module 101 illustrated in FIG. 2.

The coil L is connected between the voltage input portion Vin and the switching-element-incorporating IC 4. The switching-element-incorporating IC 4 is connected to the coil L, the voltage output portion Vout, and the first ground electrode G13.

Specifically, the first end of the coil L is connected to the voltage input portion Vin and the second end of the coil L is connected to the input end IP of the switching-element-incorporating IC 4. The output end OP of the switching-element-incorporating IC 4 is connected to the voltage output portion Vout and the first ground end GP of the switching-element-incorporating IC4 is connected to the first ground electrode G13. The first end E1a of the input capacitor C1 is connected to the voltage input portion Vin and the second end E2a of the input capacitor C1 is connected to the first ground electrode G11. The first end E1b of the output capacitor C2 is connected to the voltage output portion Vout and the second end E2b of the output capacitor C2 is connected to the first ground electrode G12. The shield cover 2 is connected to the second ground electrode G2.

The DC-DC converter module 107C illustrated in FIG. 13C is an example of a step-up/down DC-DC converter module. The DC-DC converter module 107C differs from the DC-DC converter module 101 according to the first preferred embodiment in that it includes the first ground electrode G14. The remaining configuration is the same or substantially the same as that of the DC-DC converter module 101 illustrated in FIG. 2.

The switching-element-incorporating IC 4 is connected between the voltage input portion Vin and the voltage output portion Vout. The coil L is connected to the output end OP of the switching-element-incorporating IC 4 and the first ground electrode G14.

Specifically, the input end IP of the switching-element-incorporating IC 4 is connected to the voltage input portion Vin, the output end OP of the switching-element-incorporating IC 4 is connected to the voltage output portion Vout, and the first ground end GP of the switching-element-incorporating IC4 is connected to the first ground electrode G13. The first end of the coil L is connected to the output end OP of the switching-element-incorporating IC 4 and the second end of the coil L is connected to the first ground electrode G14. The first end E1a of the input capacitor C1 is connected to the voltage input portion Vin and the second end E2a of the input capacitor C1 is connected to the first ground electrode G11. The first end E1b of the output capacitor C2 is connected to the voltage output portion Vout and the second end E2b of the output capacitor C2 is connected to the first ground electrode G12. The shield cover 2 is connected to the second ground electrode G2.

The planar shape of the substrate 1 is rectangular or substantially rectangular in the above-described preferred embodiments, but does not necessarily have to be rectangular or substantially rectangular. The planar shape of the substrate 1 may be changed as appropriate within the range in which the advantageous effects of preferred embodiments of the present invention are achieved, and may be, for example, a circle, an ellipse, or a polygon. The shape of the DC-DC converter module is a rectangular or substantially rectangular parallelepiped in the above-described preferred embodiments, but may be changed as appropriate within the range in which the advantageous effects of the present invention are achieved.

In the above-described preferred embodiments, the DC-DC converter module includes the coil element 3, the switching-element-incorporating IC 4, and the capacitor elements 21 and 22. However, electronic components included in the DC-DC converter module are not limited to those described above. The number of electronic components included in the DC-DC converter module, the types of the electronic components, and the arrangement of the electronic components may be changed as appropriate within the range in which the advantageous effects of the present invention are achieved.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A DC-DC converter module comprising:
a substrate;
a first ground electrode and a second ground electrode disposed at the substrate;
a switching-element-incorporating IC including an input end, an output end, and a first ground end;
a coil element connected to the input end or the output end;
a capacitor element including a first end connected to the input end or the output end and a second end connected to the first ground electrode; and
a shield cover that is connected to the second ground electrode and covers at least one of the switching-element-incorporating IC, the coil element, and the capacitor element which is disposed on a surface of the substrate.

2. The DC-DC converter module according to claim 1, wherein the first ground end and the shield cover are electrically connected.

3. The DC-DC converter module according to claim 1, further comprising:
a protection member that is disposed on a surface of the substrate and covers at least one of the switching-element-incorporating IC, the coil element, and the capacitor element which is disposed on the surface of the substrate; wherein
the shield cover includes a conductor disposed on a surface of the protection member.

4. The DC-DC converter module according to claim 1, wherein
the substrate is a resin substrate; and
the switching-element-incorporating IC is buried in the substrate.

5. The DC-DC converter module according to claim 1, wherein
the substrate is a ferrite substrate; and
the coil element includes a conductor disposed at the substrate.

6. The DC-DC converter module according to claim 1, wherein the substrate is a multilayer body including a magnetic substrate layer and non-magnetic layers sandwiching the magnetic substrate layer.

7. The DC-DC converter module according to claim 1, wherein the first ground electrode and the second ground electrode are provided on a main surface of the substrate.

8. The DC-DC converter module according to claim 1, wherein the switching-element-incorporating IC is a microprocessor chip or an IC chip.

9. The DC-DC converter module according to claim 1, wherein the switching-element-incorporating IC is buried in the substrate.

10. A DC-DC converter module comprising:
a substrate;
a ground electrode disposed at the substrate;
a switching-element-incorporating IC including an input end, an output end, and a first ground end;
a coil element connected to the input end or the output end;
a capacitor element including a first end connected to the input end or the output end and a second end connected to the ground electrode; and
a shield cover that is connected to the ground electrode and covers at least one of the switching-element-incorporating IC, the coil element, and the capacitor element which is disposed on a surface of the substrate; wherein
the second end and the shield cover are physically connected and are electrically disconnected at a frequency higher than or equal to a predetermined frequency.

11. The DC-DC converter module according to claim 10, wherein an inductor that has a predetermined inductance component at the predetermined frequency is connected between the second end and the shield cover.

12. The DC-DC converter module according to claim 11, wherein the inductor includes a conductive pattern disposed at the substrate.

13. The DC-DC converter module according to claim 11, wherein the inductor includes an interlayer connection conductor disposed at the substrate.

14. The DC-DC converter module according to claim 10, wherein the first ground end and the shield cover are electrically connected.

15. The DC-DC converter module according to claim 10, further comprising:
a protection member that is disposed on a surface of the substrate and covers at least one of the switching-element-incorporating IC, the coil element, and the capacitor element which is disposed on the surface of the substrate; wherein
the shield cover is a conductor disposed on a surface of the protection member.

16. The DC-DC converter module according to claim 10, wherein
the substrate is a resin substrate; and
the switching-element-incorporating IC is buried in the substrate.

17. The DC-DC converter module according to claim 10, wherein
the substrate is a ferrite substrate; and
the coil element includes a conductor disposed at the substrate.

18. The DC-DC converter module according to claim 10, wherein the substrate is a multilayer body including a magnetic substrate layer and non-magnetic layers sandwiching the magnetic substrate layer.

19. The DC-DC converter module according to claim 10, wherein the switching-element-incorporating IC is a microprocessor chip or an IC chip.

20. The DC-DC converter module according to claim 10, wherein the switching-element-incorporating IC is buried in the substrate.
